(19) United States
(12) Patent Application Publication
(10) Pub. No.: US 2020/0233033 A1
(43) Pub. Date: Jul. 23, 2020

(54) TEST PROBE FOR WAFER-LEVEL AND PANEL-LEVEL TESTING

(71) Applicant: Intel Corporation, Santa Clara, CA (US)

(72) Inventor: Hyoung Il KIM, Folsom, CA (US)

(21) Appl. No.: 16/250,712

(22) Filed: Jan. 17, 2019

(51) Int. Cl. G01R 31/3185; G01R 1/073; G01R 31/26; G01R 1/067

(52) U.S. Cl. CPC G01R 31/318511; G01R 1/06761; G01R 31/2601; G01R 1/07314

(57) ABSTRACT

Embodiments described herein provide techniques for wafer-level and panel-level testing of semiconductor devices. In one embodiment, a probe card comprises a probe card substrate and an array of test probes that extend outward from the probe card substrate. Each test probe has a blunt tip (i.e., a tip that is not sharp or pointed). An anisotropic conductive adhesive (ACA) may be formed on the test probes' blunt tips or disposed on a wafer or panel comprising contact pads formed therein or thereon. In one scenario, the test probes are brought in contact with the ACA, which is in contact with contact pads on or in a wafer or panel. The contacting of the ACA on the contact pads with the test probes forms electrical connections between test probes and the contact pads. In this way, the contact pads can be tested.

### BACKGROUND

### Field

Embodiments described herein generally relate to semiconductor packaging. More particularly, but not exclusively, embodiments described herein relate to a test probe for wafer-level and panel-level testing.

### Background Information

Pressures to miniaturize electronic devices and improve these devices' performance (e.g., processing power, etc.) has led to increased pressure to reduce sizes (e.g., z-heights, etc.) of semiconductor packages and increase input/output (I/O or TO) densities of such packages. These smaller packages, however, are susceptible to warpage induced misalignment and mechanical damage.

At the wafer- or panel-level, dies formed in or on a wafer or panel are tested to ensure proper operation. One technique of testing these dies involves the use of a probe card comprising metal test probes with sharp tips that extend outward from a surface of the probe card. For example, and with regard to FIG. 1, a probe card 105 comprising multiple test probes 107 is shown in physical contact with multiple contact pads 103 formed in a substrate 101 (e.g., a wafer-level package substrate, a panel-level package substrate, etc.). Testing is performed by contacting the sharp probe tips of the test probes 107 with the contact pads 103, passing a current through the test probes 107 to the contact pads 103, and measuring electrical characteristics associated with contact pads 103 (e.g., voltage, resistivity, etc.). This testing technique requires each test probe 107 to physically contact a single contact pad 103.

Test probes with sharp tips (e.g., test probes 107, etc.) suffer from several drawbacks. One drawback is that the test probes must be spaced apart at a sufficient pitch to prevent electrical shorts that could occur when test probes physically contact each other. Consequently, the pitch between the test probes (e.g., test probes 107, etc.) can limit the achievable pitch (e.g., pitch P₀ shown in FIG. 1, etc.) between the contact pads (e.g., contact pads 103, etc.). For example, the test probes 107 cannot be used to test contact pads with fine or ultra-fine pitches (e.g., pitches that are less than 40 μm). Another drawback is that demand for fine or ultra-fine pitches (P₀<40 μm) tightens or reduces tip width (W₀). However, probe tip length (H₀) cannot be reduced much due to the warpage of probe card (e.g., probe card 105, etc.) at elevated temperatures. Consequently, the aspect ratio (e.g., ratio of H₀ to W₀ shown in FIG. 1, etc.) makes the test probe 107s' tips fragile, which in turn makes the test probes 107 easily bendable or breakable. Broken test probes prevent testing of contact pads. Bent test probes can result in test probes that are in physical contact with each other. Yet another drawback is that, when the test probes' sharp tips are in physical contact with the contact pads, the sharp tips can damage the contacts pads and/or the substrate. For example, a sharp tip of a test probe 107 may be dragged across a surface of a contact pad 103, which results in a scrub mark that negatively affects the proper operation of the contact pad 103.

The drawbacks discussed above reduce the yield associated with semiconductor packaging and manufacturing techniques. Thus, testing semiconductor packages using test probes with sharp tips remains suboptimal.

### BRIEF DESCRIPTION OF THE DRAWINGS

Embodiments described herein are illustrated by way of example and not limitation in the figures of the accompanying drawings, in which like references indicate similar features. Furthermore, in the figures, some conventional details have been omitted so as not to obscure from the inventive concepts described herein.

FIG. 1 is a cross sectional side view illustration of a conventional probe card that has conventional test probes with sharp tips.

FIG. 2 is a cross sectional side view illustration of a probe card that has test probes with blunt tips, according to one embodiment.

FIGS. 3A-3B are cross sectional side view illustrations of probe cards comprised of test probes with blunt tips that are encapsulated by anisotropic conductive adhesives (ACAs), according to several embodiments.

FIGS. 4A-4D are cross sectional side view illustrations of a method of using an ACA and a probe card that has test probes with blunt tips for wafer-level and panel-level testing, according to one embodiment.

FIGS. 5A-5C are cross sectional side view illustrations of a method of using an ACA and a probe card that has test probes with blunt tips for wafer-level and panel-level testing, according to another embodiment.

FIGS. 6A-6C are cross sectional side view illustrations of a method of using an ACA and a probe card that has test probes with blunt tips for wafer-level and panel-level testing, according to yet another embodiment.

FIG. 7 is a schematic illustration of a computer system, according to one embodiment.

### DETAILED DESCRIPTION

In the following description, numerous specific details are set forth, such as specific material and structural regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments described herein are directed to test probes for wafer-level and panel-level testing. In one embodiment, a probe card comprises a probe card substrate and an array of test probes that extend outward from the probe card substrate. Each test probe has sidewalls and a contact surface coupling the sidewalls to each other. Each test probe's contact surface is substantially parallel to the probe card substrate. Also, each test probe's sidewall surfaces are substantially perpendicular (e.g., orthogonal, etc.) to the probe card substrate.

Each test probe has a “blunt” tip. As used herein, a test probe's blunt tip can comprise: (i) the test probe's contact surface; or (ii) the test probe's contact surface and the test probe's sidewall surfaces that are proximate to the contact surface. For brevity, a test probe's blunt tip is sometimes referred to herein as a contact surface and/or sidewall surfaces proximate to the contact surface. In one embodiment, test probes with blunt tips have a pitch that is less than 40 μm. In one embodiment, a test probe with a blunt tip has an aspect ratio (i.e., a ratio of height to width) that ranges from 1:1 to 3:1.

In one embodiment, an anisotropic conductive adhesive (ACA) encapsulates the blunt tips of the test probes. In one embodiment, each blunt tip is encapsulated by a discrete ACA portion. In one embodiment, all the blunt tips are encapsulated by a single ACA portion. In one embodiment, a thickness of the ACA over the contact surface of a test probe ranges from 1 μm to 100 μm. In one embodiment, the test probes having the ACA on their blunt tips are brought in contact with contact pads formed in or on a wafer or panel. In one embodiment, an ACA encapsulates a surface of a wafer or panel and surfaces of contact pads formed in or on the wafer or panel.

ACAs are formed from anisotropic materials (e.g., a dielectric material having conductive particles therein, etc.). The ACA remains insulating when it is not compressed. That is, in an uncompressed state, the conductive particles of the ACA are electrically isolated from each other by the dielectric material of the ACA, and current does not flow through the ACA. However, when a portion of the ACA is compressed, conductive particles in the compressed region of the ACA are squeezed together and create an electrical path through the ACA. Portions of the ACA that are not compressed remain insulated from the electrical connection by the dielectric material. An ACA can be in film form or paste form. When the ACA is a film, it may be applied by lamination. When the ACA is a paste, it may be applied by a dispensing or printing technique.

Testing a wafer or panel can be performed using a probe card that has test probes with blunt tips that are encapsulated by an ACA. In one embodiment, a test probe corresponds to a contact pad formed in or on a wafer or panel. In one embodiment, the test probe's blunt tip is encapsulated by an ACA. Furthermore, the ACA, which is on the test probe's blunt tip, is brought in physical contact with the contact pad. In particular, a load is applied to the test probe to bring the ACA on the test probe's blunt tip in physical contact with the contact pad. Compressing the ACA creates an electrical connection between the test probe and the corresponding contact pad. Subsequently, testing of the wafer or panel can be performed.

Testing a wafer or panel can also be performed using: (i) an ACA that is on a surface of a wafer or panel; and (ii) a probe card that has test probes with blunt tips. In one embodiment, a test probe's blunt tip is brought in contact with an ACA on a wafer or panel. The blunt tip compresses the ACA, and creates an electrical connection between the test probe and the corresponding contact pad. Afterwards, testing of the wafer or panel can be performed.

Several advantages accrue from the embodiments described herein. One advantage is that the test probes with blunt tips do not have to be in direct contact with the wafer or panel (e.g., the contact pads formed in or on the wafer or panel, etc.). Preventing the test probes from coming into physical contact with the wafer or panel reduces the likelihood of damage to the wafer or panel (e.g., scratching of the contact pads by the test probes, etc.). The reduced likelihood of damage can assist with increasing the yield associated with the wafer or panel. Increasing the yield associated with the wafer or panel can assist with reducing costs associated with semiconductor manufacturing and packaging. Correspondingly, preventing the test probes from coming into physical contact with the wafer or panel reduces the likelihood of damage to the test probes (e.g., bending or breaking of testing probes, etc.). Reducing damage to the test probes can improve the longevity of the test probes. Improving the longevity of the test probes can assist with reducing costs associated with semiconductor packaging and manufacturing.

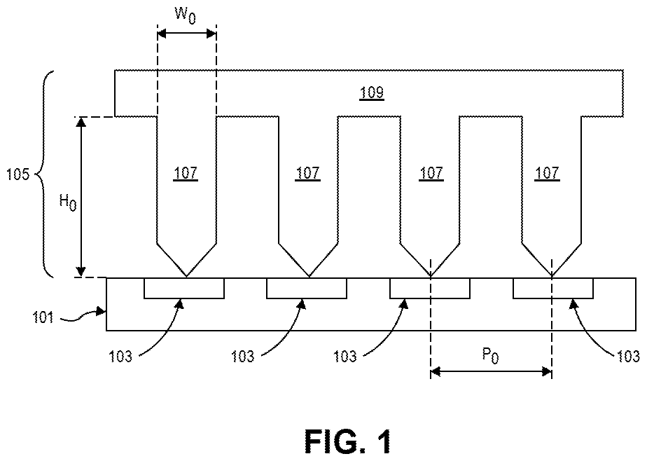

Yet another advantage is that the pitch between the test probes can be reduced (when compared to test probes having sharp tips as described above in connection with FIG. 1). As a result, wafer- or panel-level testing that includes use of an ACA and test probes with blunt tips can be used to test contact pads having fine or ultra-fine pitches (e.g., pitches of less than 40 μm, etc.).

Furthermore, wafer-level or panel-level testing that includes use of an ACA and test probes with blunt tips does not require the test probes to be perfectly aligned with the contact pads being tested. This is because the ACA creates an electrical connection between the test probes and their corresponding contact pads when the test probes are brought in contact with the ACA and the ACA is brought in contact with the contact pads. Relaxing alignment requirements can in turn assist with reducing costs associated with semiconductor packaging and manufacturing. Another related advantage is that the ACA can assist with distributing stresses because the ACA acts as a stress-absorbing buffer between test probes and the contact pads formed in or on a wafer or panel.

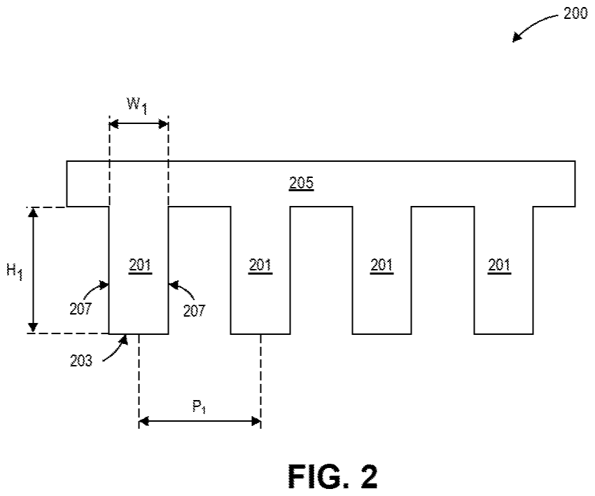

FIG. 2 is a cross sectional side view illustration of a probe card 200 that has test probes 201 with blunt tips 203, according to one embodiment. With regard now to FIG. 2, a probe card 200 is shown. The probe card 200 can be a wafer-level probe card or a panel-level probe card. In one embodiment, the probe card 200 includes a probe card substrate 205 and multiple test probes 201. The probe card substrate 205 can be formed from a dielectric material (e.g., ceramic, etc.), a metallic material (e.g., copper, etc.), a combination of a dielectric material and a metallic material, or any other suitable material or combination of suitable materials.

Each test probe 201 includes sidewall surfaces 207 extending from a surface of the probe card substrate 205, respectively. Each test probe 201 also includes a contact surface 203 coupling the sidewall surfaces 207 to each other, respectively. In an embodiment, the sidewall surfaces 207 may be substantially orthogonal to a surface of the probe card substrate 205. In other embodiments, the sidewall surfaces 207 may be tapered. In an embodiment, the contact surface 203 may be substantially parallel to a surface of the probe card substrate 205. In other embodiments, the contact surface may be any other non-pointed surface. For example, the contact surface 203 may be a curved surface. The test probes 201 can be formed from an electrically conductive material (e.g., copper, gold, tungsten, rhenium, any other suitable electrically conductive material, or any combination thereof).

Each test probe 201 has a blunt tip, as defined above. In short, each test probe 201 has a tip that is not sharp or pointed. As explained above, a test probe 201's blunt tip can comprise: (i) the test probe 201's contact surface; or (ii) the test probe 201's contact surface and the test probe 201's sidewall surfaces that are proximate to the contact surface.

Each test probe 201 has an aspect ratio (i.e., a ratio of height H₁ to width W₁). In one embodiment, each of the test probes 201 can have any aspect ratio (e.g., 10:1, 3:2, 1:1. 1:2, etc.). Thus, embodiments of the test probes 201 are not required to have large aspect ratios. This is in contrast to the conventional test probes 107 described above in connection with FIG. 1, which require large aspect ratios that make the conventional test probes 107 susceptible to breaking or bending. In a specific embodiment, each test probe 201 with a blunt tip has an aspect ratio (i.e., a ratio of height to width) that ranges from 1:1 to 3:1.

Even though the probe card 200 is shown to include four test probes 201, other embodiments are not so limited. Specifically, and for one or more embodiments, the probe card 200 can include one or more test probes that are similar to or the same as the test probes 201. For example, the probe card 200 includes numerous test probes that are similar to or the same as the test probes 201.

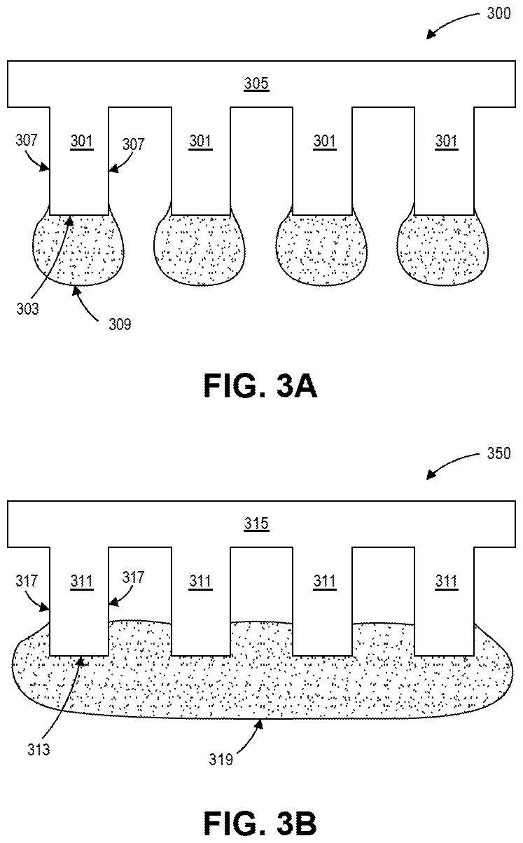

The test probes 201 may have pitches, in one embodiment. The pitches between the test probes 201 can be equal to or different from each other. In one embodiment, and with regard again to FIG. 2, the pitch P₁ may be a uniform pitch. That is, all of the test probes 201 have the same pitch P₁. In another embodiment, the pitch P₁ may be non-uniform. That is, one or more of the test probes 201 has a pitch P₁ that differs from a pitch of the other test probes 201. As shown by the embodiments above, the test probes 201 do not require uniform pitches between each other. Even though the test probes 201 may not have uniform pitches, the test probes 201 can still be used for testing contact pads formed in or on a wafer or panel. Furthermore, testing can occur even though the test probes 201 are not perfectly aligned with the contact pads, as explained in further detail below in connection with one or more of FIGS. 3A-7. Relaxing alignment requirements can assist with reducing costs associated with semiconductor packaging and manufacturing. This is in contrast with the conventional test probes 107 described above in connection with FIG. 1, which require uniform pitches and substantially perfect alignment between test probes and contact pads for testing contact pads, as described above. In one embodiment, the pitch P₁ is less than 40 μm.

FIGS. 3A-3B are cross sectional side view illustrations of probe cards 300, 350 that have test probes 301, 311 with blunt tips 303, 313 that are encapsulated by ACAs 309, 319, respectively, according to several embodiments.

With regard now to FIG. 3A, a probe card 300 is shown. The probe card 300 comprises a probe card substrate 305, which can be similar to or the same as the probe card substrate 205 described above in connection with FIG. 2A. Furthermore, the probe card 300 also includes test probes 301 that have contact surfaces 303 and sidewall surfaces 307, respectively. That is, the probe card 300 includes test probes 301 that each have blunt tips.

The test probes 301 are encapsulated by discrete ACA portions 309, respectively. That is, each test probe 301 is encapsulated by a discrete ACA portion 309 that is separate from and does not contact the discrete ACA portion 309 of a neighboring test probe 301. In an embodiment, the discrete ACA portion 309 may cover the contact surface 303 of the test probe 301. In a further embodiment, the discrete ACA portion 309 may also extend over portions of the sidewalls surfaces 307 proximate to the contact surface 303.

Each of the discrete ACA portions 309 is formed from an anisotropic material. In one embodiment, the anisotropic material used to form each of the ACA portions 309 is a dielectric material having conductive particles therein. In this embodiment, the conductive particles of the ACA portion 309 are insulated by the dielectric material of the ACA. When the discrete ACA portion 309 is compressed—for example, by contacting the discrete ACA portion 309 with a contact pad formed on or in a wafer or panel—the conductive particles within the discrete ACA portion 309 are pressed together (e.g., brought in contact with each other). The conductive particles in the compressed portion of the discrete ACA portion create an electrical connection in or through the compressed portion of the discrete ACA portion 309. In this way, the test probe 301 and a corresponding contact pad (not shown in FIG. 3A) are electrically coupled to each other.

At least one of the ACA portions 309 is in paste form. When an ACA portion is a paste, it may be applied by a dispensing or printing technique. For example, and with regard to the ACA portion 309, a dispensing or printing technique may be used to apply an ACA paste to the test probe 301's blunt tip (i.e., the contact surface 303 and/or the sidewall surfaces 307 that are proximate to the contact surface 303).

Referring now to FIG. 3B, a probe card 350 is shown. The probe card 350 is similar to the probe card 300 described above in connection with FIG. 3A, except that a single ACA portion 319 is used to encapsulate all of the test probes 311. More specifically, each test probe 311 is encapsulated by a single ACA portion 319 that also encapsulates the other test probes 311. In one embodiment, no electrical shorts are created when the single ACA portion 319 is compressed even though all the test probes 311 are encapsulated by the single ACA portion 319. This is because, when portions of the single ACA portion 319 are compressed, electrical connections are only created in the compressed portions of the single ACA portion 319. That is, only conductive particles in the compressed portions of the single ACA portion 319 create electrical connections in or through the compressed portions of the single ACA portion 319. On the other hand, the conductive particles of the single ACA portion 319 in the uncompressed portions of the single ACA portion 319 remain insulated by the dielectric material of the single ACA portion 319 and do not create electrical connections in or through the uncompressed portions of the single ACA portion 319. In this way, there are no electrical shorts created even though a single ACA portion encapsulates all of the test probes 311.

In one embodiment, the single ACA portion 319 is in film form. When the single ACA portion 319 is a film, it may be applied by lamination. For example, a lamination technique may be used to apply the single ACA film 319 to the test probe 311's blunt tips (i.e., the contact surfaces 313 and/or the sidewall surfaces 317 that are proximate to the contact surfaces 313).

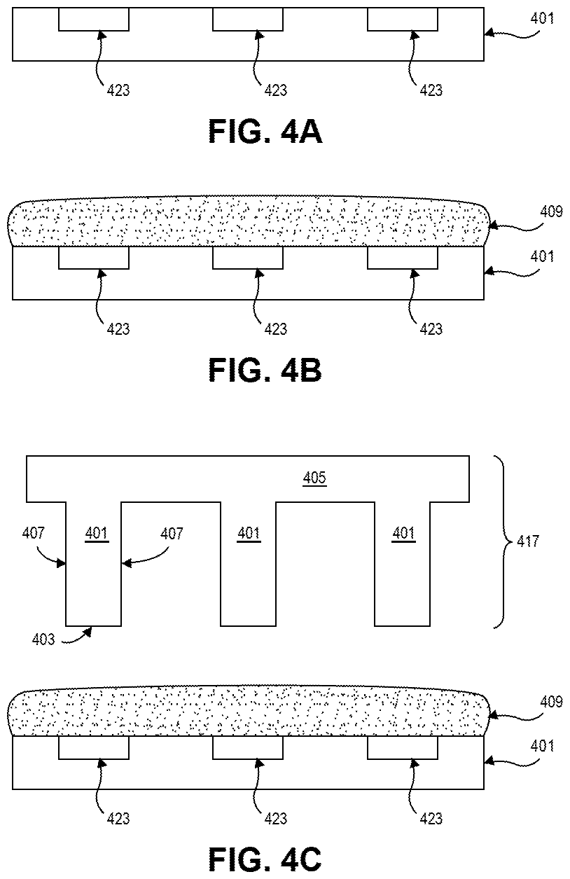

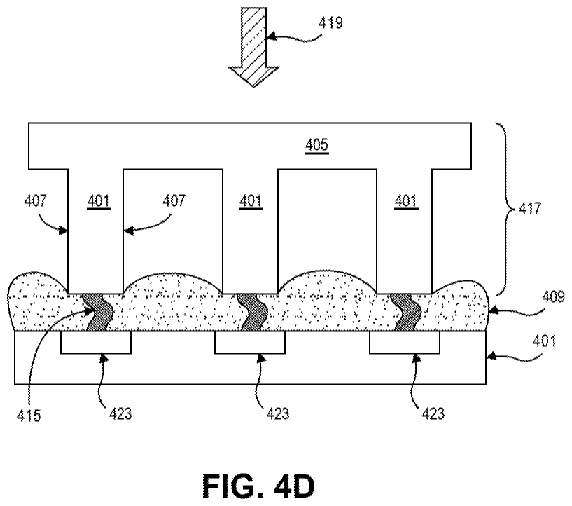

FIGS. 4A-4D are cross sectional side view illustrations of a method of using an ACA and a probe card that has test probes with blunt tips for wafer-level and panel-level testing, according to one embodiment.

Referring now to FIG. 4A, a substrate 401 comprising contact pads 423 formed thereon or therein is shown. The substrate 401 can be a wafer-level package substrate or a panel-level package substrate. The substrate can be formed from silicon or any other suitable material known in the art. Next, in FIG. 4B, an ACA 409 is deposited on a surface of the substrate 401 and on surfaces of the contact pads 423. If the ACA 409 is in film form, the ACA 409 may be laminated onto the surface of the substrate 401 and on surfaces of the contact pads 423. If the ACA 409 is in paste form, the ACA 409 may be dispensed or printed on the surface of the substrate 401 and on surfaces of the contact pads 423. In one embodiment, the ACA 409 is similar to or the same as the ACA described above in connection with FIGS. 3A-3B. That is, the ACA 409 is formed from an anisotropic material (e.g., a dielectric material having conductive particles therein, etc.).

Moving on to FIG. 4C, a probe card 417 is provided above the ACA 409. In one embodiment, the probe card 417 includes a probe card substrate 405 and test probes 401 that each have a contact surface 403 and sidewall surfaces 407. As shown, the test probes 401 extend from a surface of the probe card substrate 405. Furthermore, the contact surface 403 is substantially parallel to the surface of the probe card substrate 405 and the sidewalls surface 407 are each substantially perpendicular to the surface of the probe card substrate 405.

Next, in FIG. 4D, the probe card 417 is brought in physical contact with the ACA 409. Specifically, a load 419 is used to bring the test probes 401 in contact with the ACA 409. In one embodiment, the load 419 is applied to the probe card 417 to bring the blunt tips of the test probes 401 in physical contact with the ACA 409, which is already in contact with the contact pads 423. In an embodiment, a test probe 401 compresses the ACA 409 and produces an electrical connection through the ACA 409 from the test probe 401 to the corresponding contact pad 423. In particular, localized compression of the ACA 409 by the test probes 401 causes conductive particles of the ACA 409 to connect together to form a conductive path between a test probe 401 and its corresponding contact pad 423. Furthermore, conductive particles in non-compressed regions of the ACA 409 remain surrounded by the dielectric material of the ACA 409. Consequently, electrical connections 415 are created between the test probes 401 and their corresponding contact pads 423 without creating electrical connections throughout the entire ACA 409. Afterwards, testing of the contact pads 423 can be performed.

As noted above, the use of an ACA 409 for testing in this manner has several advantages over other testing architectures. For example, as shown in FIG. 4D, the test probes 401 never directly contact the contact pads 423. Accordingly, there is no damage to the contact pads 423. Additionally, the use of ACA 409 allows for misalignment between the test probe 401 and the contact pad 423. The formation of a conductive path through the ACA 409 by compression allows for the alignment tolerance to be relaxed.

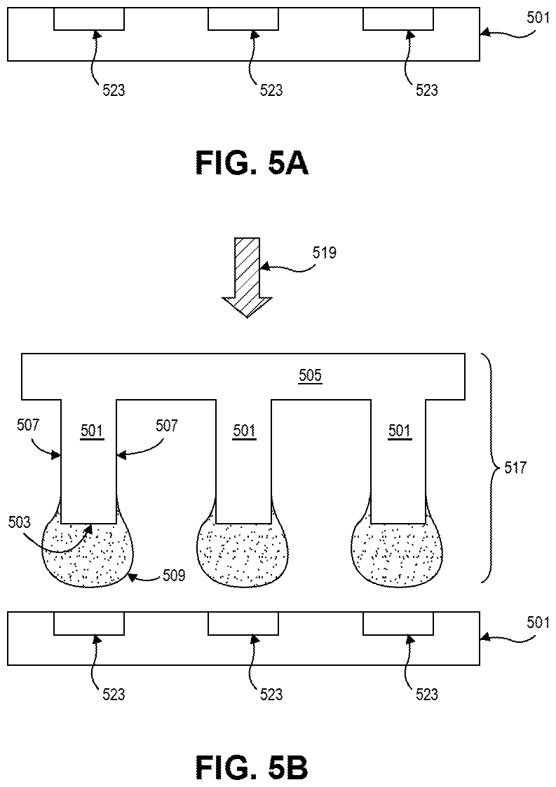

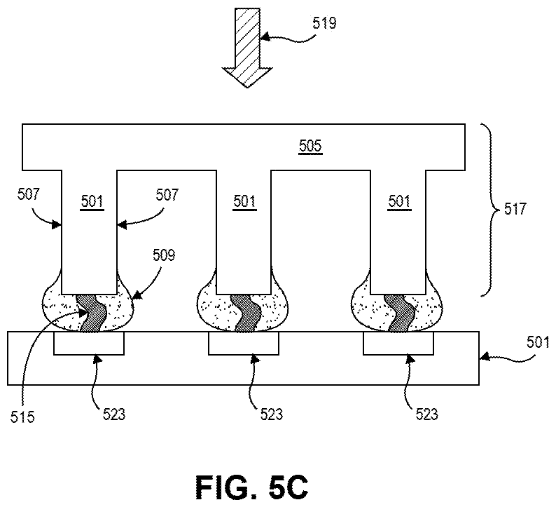

FIGS. 5A-5C are cross sectional side view illustrations of a method of using an ACA and a probe card that has test probes with blunt tips for wafer-level and panel-level testing, according to another embodiment. Referring now to FIG. 5A, a substrate 501 comprising contact pads 523 formed thereon or therein is shown. The substrate 501 can be similar to or the same as the substrate 401 described above in connection with FIGS. 4A-4D. Next, in FIG. 5B, a probe card 517 is provided above the substrate 501. The probe card 517 is similar to or the same as the probe card 300 described above in connection with FIG. 3A. For brevity, the probe card 517 is not described again.

Moving on to FIG. 5C, a load 519 is applied to the probe card 517 to bring the discrete ACA portions 509 formed on the blunt tips of the test probes 501 in physical contact with the contact pads 523. Similar to the description provided above in connection with FIGS. 4A-4D, the interaction between the test probes 501, the ACA portion 509, and the contact pads 523 enables creation of electrical connections 515 between the test probes 501 and the corresponding contact pads 523. In particular, application of a test probe 501 having a discrete ACA portion 509 formed thereon to a corresponding contact pad 523 causes at least some of the conductive particles of the discrete ACA portion 509 to form an electrical connection between the test probe 511 and the corresponding contact pad 523, while the other conductive particles that are not in physical contact with the contact pad 523 remain insulated by the dielectric material of the discrete ACA portion 509. Consequently, electrical connections 515 are created between the test probe 501 and their corresponding contact pads 523. Subsequently, testing of the contact pads 523 can be performed.

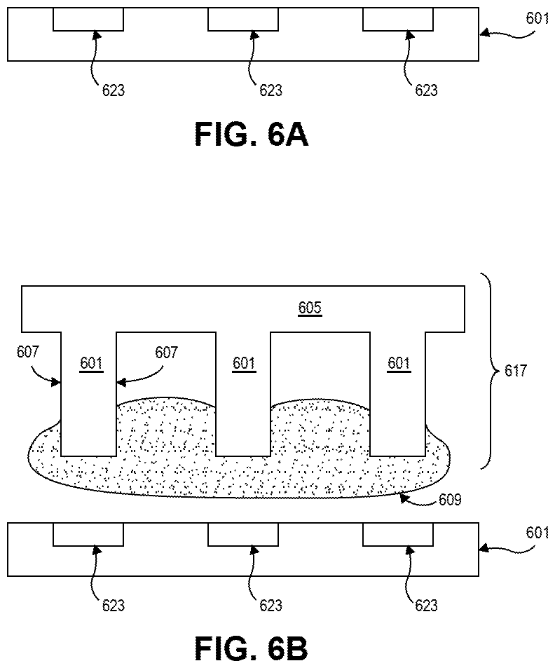

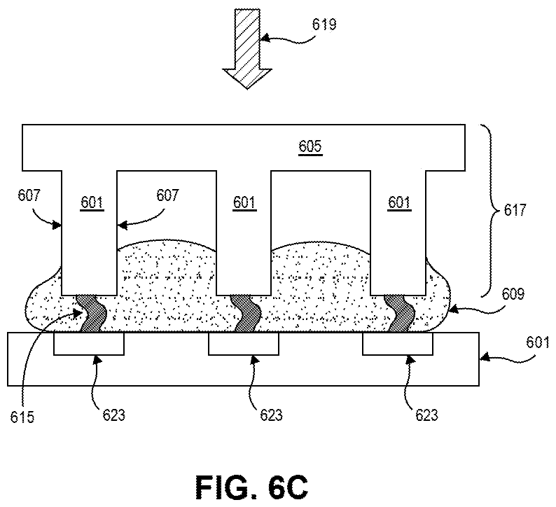

FIGS. 6A-6C are cross sectional side view illustrations of a method of using an ACA and a probe card that has test probes with blunt tips for wafer-level and panel-level testing, according to another embodiment. Referring now to FIG. 6A, a substrate 601 comprising contact pads 623 formed thereon or therein is shown. The substrate 601 can be similar to or the same as the substrate 401 described above in connection with FIGS. 4A-4D. Next, in FIG. 6B, a probe card 617 is provided above the substrate 601. The probe card 617 is similar to or the same as the probe card 350 described above in connection with FIG. 3B. For brevity, the probe card 617 is not described again.

Moving on to FIG. 6C, a load 619 is applied to the probe card 617 to bring the blunt tips of the test probes 601 in physical contact with the ACA 609, which is on the contact pads 623. Similar to the description provided above in connection with FIGS. 4A-4D, the interaction between the test probes 601, the ACA 609, and the corresponding contact pads 623 enables creation of electrical connections 615 between the test probes 601 and the corresponding contact pads 623. In particular, application of the load 619 to the probe card 617 causes the test probes 601 to physically compress some portions of the ACA 609. The compression causes some of the conductive particles of the ACA 609 to create electrical connections between the test probes 601 and the corresponding contact pads 623, while the other conductive particles that are not compressed by the test probes 601 remain insulated by the dielectric material of the ACA 609. Consequently, electrical connections 615 are created between the test probes 601 and their corresponding contact pads 623 without creating electrical connections throughout the entire ACA 609. In this way, testing of the contact pads 623 can be performed without creating electrical shorts.

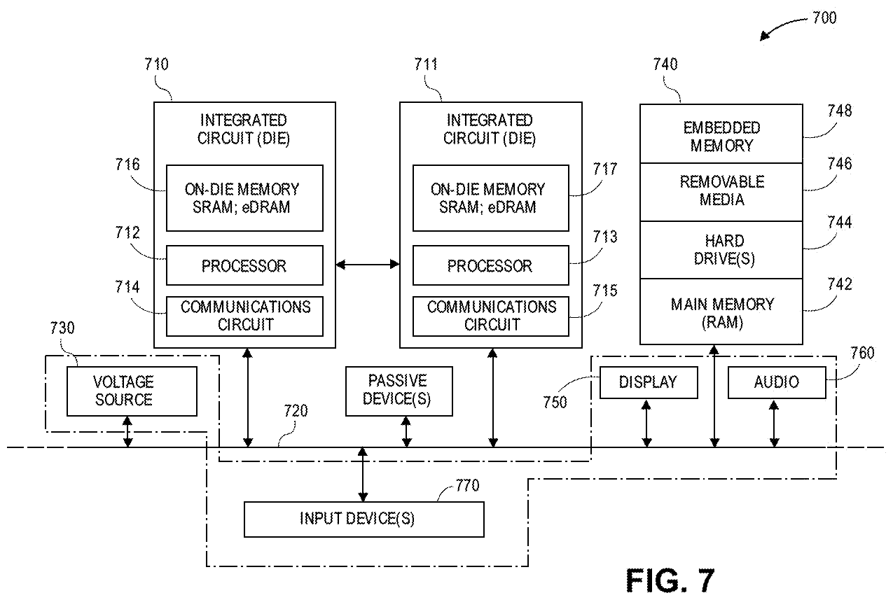

FIG. 7 illustrates a schematic of computer system 700 according to an embodiment. The computer system 700 (also referred to as an electronic system 700) can include a semiconductor package with one or more dies that have been tested using a probe card that has been designed in accordance with any of the embodiments and their equivalents as set forth in this disclosure. The computer system 700 may be a mobile device, a netbook computer, a wireless smart phone, a desktop computer, a hand-held reader, a server system, a supercomputer, or a high-performance computing system.

The system 700 can be a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In one embodiment, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712. As used herein, the processor 712 may mean any type of circuit such as, but not limited to, a microprocessor, a microcontroller, a graphics processor, a digital signal processor, or another processor. In an embodiment, the processor 712 includes, or is coupled with, a semiconductor package. In one embodiment, the integrated circuit 710 or the processor 712 is tested using a probe card that is designed in accordance with any of the embodiments and their equivalents, as described in the foregoing specification. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM). In one embodiment, the on-die memory 716 may be packaged with a suitable packaging process. In one embodiment, prior to packaging, the on-die memory 716 is tested using a probe card that is designed in accordance with any of the embodiments and their equivalents, as described in the foregoing specification.

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 710 includes embedded on-die memory 717 such as eDRAM.

In an embodiment, the electronic system 700 also includes an external memory 740 that may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also include embedded memory 748 such as the first die in a die stack, according to an embodiment. In one embodiment, prior to packaging, the embedded memory 748 is tested using a probe card that is designed in accordance with any of the embodiments and their equivalents, as described in the foregoing specification.

In an embodiment, the electronic system 700 also includes a display device 750 and an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

At least one of the integrated circuits 710 or 711 can be implemented in a number of different embodiments, including a semiconductor package, an electronic system, a computer system, one or more methods of fabricating an integrated circuit, and one or more methods of fabricating a semiconductor package. In one embodiment, prior to packaging, at least one of the integrated circuits is tested using a probe card that is designed according to any disclosed embodiments set forth herein and their art-recognized equivalents. The elements, materials, geometries, dimensions, and sequence of operations can all be varied to suit particular I/O coupling requirements including array contact count, array contact configuration for a microelectronic die embedded in a processor mounting substrate. A foundation substrate may be included, as represented by the dashed line of FIG. 7. Passive devices may also be included, as is also depicted in FIG. 7.

Reference throughout this specification to “one embodiment,” “an embodiment,” “another embodiment” and their variations means that a particular feature, structure, configuration, or characteristic described in connection with the embodiment is included in at least one embodiment. Thus, the appearances of the phrase “for one embodiment,” “In an embodiment,” “for another embodiment,” “in one embodiment,” “in an embodiment,” “in another embodiment,” or their variations in various places throughout this specification are not necessarily referring to the same embodiment. Furthermore, the particular features, structures, configurations, or characteristics may be combined in any suitable manner in one or more embodiments.

The terms “over,” “to,” “between,” “onto,” and “on” as used in the foregoing specification refer to a relative position of one layer with respect to other layers. One layer “over” or “on” another layer or bonded “to” or in “contact” with another layer may be directly in contact with the other layer or may have one or more intervening layers. One layer “between” layers may be directly in contact with the layers or may have one or more intervening layers.

The description provided above in connection with one or more embodiments as described herein that is included as part of a process of fabricating semiconductor packages may also be used for other types of IC packages and mixed logic-memory package stacks. In addition, the processing sequences may be compatible with WLP, PLP, and integration with surface mount substrates such as LGA, QFN, and ceramic substrates.

In the foregoing specification, abstract, and/or figures, numerous specific details are set forth, such as specific materials and processing operations, in order to provide a thorough understanding of embodiments described herein. It will, however, be evident that any of the embodiments described herein may be practiced without these specific details. In other instances, well-known features, such as the integrated circuitry of semiconductive dies, are not described in detail in order to not unnecessarily obscure embodiments described herein. Furthermore, it is to be understood that the various embodiments shown in the Figures and described in connection with the Figures are illustrative representations and are not necessarily drawn to scale. Thus, various modifications and/or changes may be made without departing from the broader spirit and scope of the embodiments described in connection with the foregoing specification, abstract, and/or Figures. As used herein, the phrases “A or B”, “A and/or B”, “one or more of A and B”, and “at least one of A or B” means (A), (B), or (A and B).

Embodiments described herein include a probe card, comprising: a substrate; an array of test probes that extend outward from a surface of the substrate, wherein each test probe comprises sidewall surfaces and a contact surface opposite from the substrate, the contact surface coupling the sidewall surfaces to each other; and an anisotropic conductive adhesive (ACA) over the contact surface of each of the test probes.

Additional embodiments include a probe card, wherein the contact surface is substantially parallel to the surface of the substrate.

Additional embodiments include a probe card, wherein the ACA comprises a film that spans between the tests probes.

Additional embodiments include a probe card, wherein the ACA comprises a plurality of discrete ACA portions, and wherein a different one of the plurality of discrete ACA portions is over each of the contact surfaces of the test probes.

Additional embodiments include a probe card, wherein the ACA extends along sidewall surfaces proximate to the contact surfaces.

Additional embodiments include a probe card, wherein the test probes have a pitch that is less than 40 micrometers (μm).

Additional embodiments include a probe card, wherein the probe card is a wafer-level probe card.

Additional embodiments include a probe card, wherein each of the test probes has an aspect ratio that ranges from 1:1 to 3:1 and wherein the aspect ratio is a ratio of height to width.

Additional embodiments include a probe card, wherein a thickness of the ACA over the contact surface is 1 micrometer (μm) to 100 μm.

Additional embodiments include a probe card, wherein sidewall surfaces of the test probes are substantially perpendicular to the surface of the substrate.

Embodiments described herein include a method, comprising: disposing an anisotropic conductive adhesive (ACA) on a first substrate, wherein the first substrate comprises a plurality of contact pads, and wherein a surface of the first substrate and surfaces of the plurality of contact pads are encapsulated by the ACA; and contacting the ACA with a probe card, the probe card comprising a second substrate; and an array of test probes that extend outward from a surface of the second substrate, wherein each test probe comprises sidewall surfaces and a contact surface opposite from the second substrate and wherein the contact surface couples the sidewall surfaces to each other.

Additional embodiments include a method, wherein contacting the ACA with the probe card comprises: directly contacting the contact surfaces of the test probes with the ACA.

Additional embodiments include a method, wherein each contact surface is substantially parallel to the surface of the probe card substrate.

Additional embodiments include a method, wherein the test probes compress the ACA and form conductive paths through the ACA and wherein each conductive path electrically couples a contact pad to a contact surface of a test probe to form a contact pad and contact surface pair.

Additional embodiments include a method, wherein each contact pad and contact surface pair are aligned.

Additional embodiments include a method, wherein one or more of the contact pad and contact surface pairs are misaligned.

Additional embodiments include a method, wherein the first substrate is a wafer-level package substrate.

Additional embodiments include a method, wherein the first substrate is a panel-level package substrate.

Additional embodiments include a method, wherein the second substrate is a probe card substrate.

Embodiments described herein include a method, comprising: providing a substrate with devices to be tested, wherein the devices comprise contact pads; and testing the substrate with a probe card, wherein the probe card compresses an anisotropic conductive adhesive (ACA) positioned between the probe card and the substrate.

Additional embodiments include a method, wherein the ACA is attached to the probe card.

Additional embodiments include a method, wherein the ACA is attached to the substrate.

Additional embodiments include a method, wherein the probe card comprises a plurality of test probes each with a contact surface, wherein each of the test probes corresponds to one of the contact pads, and wherein the compressed ACA provides a conductive path between the contact surface and the corresponding contact pad.

Additional embodiments include a method, wherein the contact surface and the corresponding contact pad are aligned.

Additional embodiments include a method, wherein the contact surface and the corresponding contact are misaligned.

1. A probe card, comprising:
a substrate;
an array of test probes that extend outward from a surface of the substrate, wherein each test probe comprises sidewall surfaces and a contact surface opposite from the substrate, the contact surface coupling the sidewall surfaces to each other; and
an anisotropic conductive adhesive (ACA) over the contact surface of each of the test probes.

2. The probe card of claim 1, wherein the contact surface is substantially parallel to the surface of the substrate.

3. The probe card of claim 1, wherein the ACA comprises a film that spans between the tests probes.

4. The probe card of claim 1, wherein the ACA comprises a plurality of discrete ACA portions, and wherein a different one of the plurality of discrete ACA portions is over each of the contact surfaces of the test probes.

5. The probe card of claim 1, wherein the ACA extends along sidewall surfaces proximate to the contact surfaces.

6. The probe card of claim 1, wherein the test probes have a pitch that is less than 40 micrometers (μm).

7. The probe card of claim 1, wherein the probe card is a wafer-level probe card.

8. The probe card of claim 1, wherein each of the test probes has an aspect ratio that ranges from 1:1 to 3:1 and wherein the aspect ratio is a ratio of height to width.

9. The probe card of claim 1, wherein a thickness of the ACA over the contact surface is 1 micrometer (μm) to 100 μm.

10. The probe card of claim 1, wherein sidewall surfaces of the test probes are substantially perpendicular to the surface of the substrate.

11. A method, comprising:
disposing an anisotropic conductive adhesive (ACA) on a first substrate,
wherein the first substrate comprises a plurality of contact pads, and
wherein a surface of the first substrate and surfaces of the plurality of contact pads are encapsulated by the ACA; and
contacting the ACA with a probe card, the probe card comprising
a second substrate; and
an array of test probes that extend outward from a surface of the second substrate, wherein each test probe comprises sidewall surfaces and a contact surface opposite from the second substrate and wherein the contact surface couples the sidewall surfaces to each other.

12. The method of claim 11, wherein contacting the ACA with the probe card comprises:
directly contacting the contact surfaces of the test probes with the ACA.

13. The method of claim 12, wherein each contact surface is substantially parallel to the surface of the probe card substrate.

14. The method of claim 12, wherein the test probes compress the ACA and form conductive paths through the ACA and wherein each conductive path electrically couples a contact pad to a contact surface of a test probe to form a contact pad and contact surface pair.

15. The method of claim 14, wherein each contact pad and contact surface pair are aligned.

16. The method of claim 14, wherein one or more of the contact pad and contact surface pairs are misaligned.

17. The method of claim 11, wherein the first substrate is a wafer-level package substrate.

18. The method of claim 11, wherein the first substrate is a panel-level package substrate.

19. The method of claim 11, wherein the second substrate is a probe card substrate.

20. A method, comprising:
providing a substrate with devices to be tested, wherein the devices comprise contact pads; and
testing the substrate with a probe card, wherein the probe card compresses an anisotropic conductive adhesive (ACA) positioned between the probe card and the substrate.

21. The method of claim 19, wherein the ACA is attached to the probe card.

22. The method of claim 19, wherein the ACA is attached to the substrate.

23. The method of claim 19, wherein the probe card comprises a plurality of test probes each with a contact surface, wherein each of the test probes corresponds to one of the contact pads, and wherein the compressed ACA provides a conductive path between the contact surface and the corresponding contact pad.

24. The method of claim 23, wherein the contact surface and the corresponding contact pad are aligned.

25. The method of claim 23, wherein the contact surface and the corresponding contact are misaligned.
